(19) United States
(12) Patent Application Publication
(10) Pub. No.: US 2025/0004024 A1
(43) Pub. Date: Jan. 2, 2025

(54) FULLY DIGITAL DOMAIN INTEGRATED FREQUENCY MONITOR

(71) Applicant: NVIDIA Corporation, Santa Clara, CA (US)

(72) Inventor: Ofek Abadi, Nahariya (IL)

(21) Appl. No.: 18/216,408

(22) Filed: Jun. 29, 2023

(51) Int. Cl. G01R 23/00; G01R 15/04; G01R 19/165; H03K 3/037; H03K 5/00; H03K 5/24; H03K 19/20

(52) U.S. Cl. CPC G01R 23/005; G01R 15/04; G01R 19/16576; H03K 3/037; H03K 5/00006; H03K 5/24; H03K 19/20

(57) ABSTRACT

Technologies directed to determine whether a frequency of a clock signal is outside a specified frequency range are described. One integrated circuit includes a signal generator circuit, a voltage divider circuit, and digital logic circuitry. The signal generator circuit generates phase signals from a clock signal. The voltage divider circuit converts a frequency of the clock signal to a voltage representing the frequency. The voltage divider circuit includes a first resistor and a first switched-capacitor structure to receive the phase signals. An average resistance of the first switched-capacitor structure is inversely proportional to the frequency of the clock signal. The digital logic circuitry can determine, using the voltage, whether the frequency is outside of a specified frequency range, and output an indication responsive to the frequency being outside the specified frequency range.

### TECHNICAL FIELD

At least one embodiment pertains to a fully digital domain integrated frequency monitor for monitoring a clock signal. For example, at least one embodiment pertains to technology for monitoring a clock signal to ensure that the clock signal remains within an expected frequency range.

### BACKGROUND

An oscilloscope is an electronic test instrument used to observe and analyze the characteristics of electrical signals. The oscilloscope is a widely used tool for measuring and monitoring clock signals. It captures and displays the waveform of the clock signal, allowing analysis of its frequency, amplitude, and other characteristics. Modern digital oscilloscopes often come with advanced triggering and analysis capabilities.

On-chip oscilloscopes, also known as integrated oscilloscopes or embedded oscilloscopes, are specialized circuits or modules that are integrated directly onto a microchip or an integrated circuit (IC). They are designed to provide the functionality of an oscilloscope within the confines of the microchip or IC itself.

A frequency monitor, also known as a frequency counter or frequency meter, is a device used to measure the frequency of an input signal. It provides a numerical readout of the signal's frequency, typically in hertz (Hz) or its multiples. Frequency monitors specialize in accurately determining the frequency of a periodic signal. They count the number of cycles of the input signal within a specified time interval to calculate the frequency. Frequency monitors have a specific frequency range they can measure. Frequency monitors primarily provide information about the frequency of the input signal. They do not necessarily display the waveform or other time-based characteristics like oscilloscopes.

An on-chip frequency monitor, also known as an integrated frequency monitor or embedded frequency counter, is a specialized circuit or module integrated directly onto a microchip or an IC. Its purpose is to measure and monitor the frequency of signals within the circuit.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram of an integrated circuit with a fully digital domain integrated frequency monitor according to at least one embodiment.

FIG. 2 is a circuit diagram of a fully digital domain integrated frequency monitor according to at least one embodiment.

FIG. 3A is a graph showing an input clock frequency being raised to a higher frequency according to at least one embodiment.

FIG. 3B is a graph showing an input clock frequency being reduced to a lowered frequency according to at least one embodiment.

FIG. 4 is a graph showing the supply voltage transitions as a function of time according to at least one embodiment.

FIG. 5 is a graph showing supply voltage noise attenuation according to at least one embodiment.

FIG. 6A is a circuit diagram of a non-overlapping clock generator according to at least one embodiment.

FIG. 6B is a graph illustrating an input clock and four phase signals generated by the non-overlapping clock generator of FIG. 6A according to at least one embodiment.

FIG. 7 illustrates an equivalent model of a switch-capacitor as an effective resistor according to at least one implementation.

FIG. 8 is a schematic diagram of a fully differential switched-capacitor structure according to at least one embodiment.

FIG. 9 is a schematic diagram of clock gates for the fully differential switched-capacitor structures according to at least one embodiment.

FIG. 10 is a schematic diagram of a programmable resistor according to at least one embodiment.

FIG. 11 is a schematic diagram of an N-bit Resistor-Ladder DAC according to at least one embodiment.

FIG. 12 is a flow diagram of a method for determining whether a frequency of a clock signal is outside a specified frequency range according to at least one embodiment.

FIG. 13 is a block diagram of a computing system with a frequency monitor according to at least one embodiment.

### DETAILED DESCRIPTION

Technologies directed to determine whether a frequency of a clock signal is outside a specified frequency range are described. In electronics, and especially in synchronous digital circuits, a clock signal which oscillates at a specific frequency is used to synchronize actions of digital circuits. In a synchronous logic circuit, the most common type of digital circuit, the clock signal is applied to all storage devices, flip-flops, and latches and causes them all to change state simultaneously, preventing race conditions. Most integrated circuits (ICs) of sufficient complexity use a clock signal in order to synchronize different parts of the circuit.

In complex ICs such as CPU, GPU, Switch, HCA, DPU, etc., clocks signals are used intensively in digital and analog circuits. In such systems, the reference clock (the clock signal from which all the other synchronous clocks in the system are derived) is often fed by an external oscillator located on a circuit board to which the IC is coupled.

For various purposes, including security, there is a requirement to ensure that various system clocks stay within an expected frequency range. The various system clocks can include clocks fed directly by external sources and various on-die internal clocks generated based on programmable dividers and phased-locked loops (PLLs).

Frequency deviations of the clock signal from an expected range might cause a technical failure or an unexpected result in both digital and analog circuits. One major security concern is a malicious attempt to change the external reference clock frequency such that it will cause unexpected behavior of the internal circuits and will be used to hack into the system or cause reliability issues. Therefore, an accurate frequency monitor can assist by indicating that such an attempt is happening and allowing the system to take some actions in defense.

Another usage of a frequency monitor can be for design-for-test (DFT) purposes. Since it can be used to indicate that certain clocks are within an expected range, if some of them deviate from that range, a production or design issue can be detected, especially in the external oscillator, which is often the source of all other clocks in the system.

A common way of monitoring the frequency range of clock signals is by generating another uncorrelated internal clock with a known frequency (most often calibrated to a specific frequency during the production phase of the chip) and comparing their frequencies to decide the ratio between them. The internal clock is often generated by a Ring-Oscillator or Relaxation-Oscillator inside the chip, most often requiring low noise analog supply. Furthermore, in order to compare the two frequencies, some kind of a digital counter is needed. The digital output of this block is a representation of the ratio between the two frequencies. Since the internals' oscillator frequency is known (to some extent), the input clock's frequency can be calculated by knowing this ratio.

Besides the need for a quiet analog supply, the internal oscillators depend substantially on process parameters and temperature variation. This dependency limits their accuracy, even in case calibration is performed.

Aspects and embodiments of the present disclosure overcome the deficiencies described above and others by providing an on-die functional unit (e.g., also referred to as a digital block or IP block) that can be fully integrated into digital domain areas. The functional unit gets a clock signal as its input, and its main function is verifying that the frequency of this clock signal is within a specified range. The on-die functional unit can contain a voltage divider with switched capacitors in series with a configurable poly-resistor. An input clock, which could have a verified frequency range) can be connected to a non-overlapping converter, and the output of this converter can be sent to the switched-capacitor structures. The switched capacitors' effective resistance is proportional to the input clock frequency. A comparator compares the voltage divider's output signal to a reference voltage (generated by a resistor ladder with a configurable output multiplexer (MUX)). The comparator's output is sampled by a DFF, which can be fed by a divided input clock. The poly-resistor configurable value is calibrated by a known reference frequency during production. The resistor ladder's output can be selected such that different frequency thresholds can be compared to the input clock's frequency. Unlike conventional solutions, the on-die functional unit does not generate an additional clock with an internal oscillator but instead converts the input clock's frequency to voltage. The on-die functional unit can consume less power, have higher frequency before and after calibration, and consume less area compared to conventional solutions.

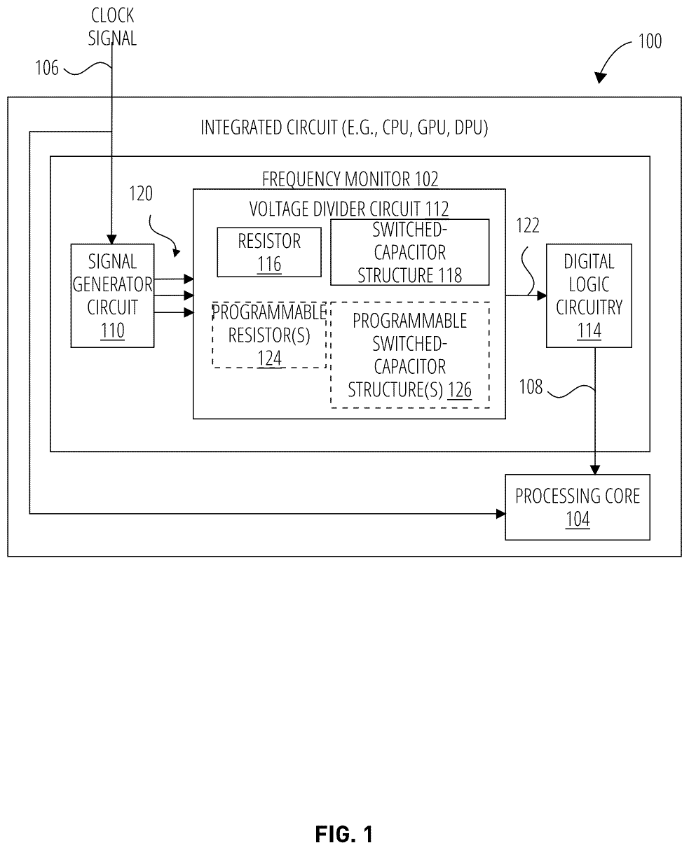

FIG. 1 is a block diagram of an integrated circuit 100 with a fully digital domain integrated frequency monitor 102 according to at least one embodiment. The integrated circuit 100 includes a processing core 104 that receives a clock signal 106. The processing core 104 can be a processor core of a central processing unit (CPU), a core of a graphics processing unit (GPU), a core of a data processing unit (DPU), or the like. Alternatively, the integrated circuit 100 includes other circuits than the processing core 104 that can receive the clock signal 106. The clock signal 106 can be an external clock signal or an internal clock signal. In at least one embodiment, the clock signal 106 can be received from an external clock source, such as a crystal oscillator on a circuit board upon which the integrated circuit 100 is disposed. In at least one embodiment, the clock signal can be received from an on-die clock source, such as a programmable clock divider, a phased-locked loop (PLL), or the like. As described above, the clock signal 106 should stay within an expected frequency range for various purposes. The frequency monitor 102 can be used to monitor the clock signal 106 to ensure that the clock signal 106 stays within the expected frequency range. The frequency monitor 102 can be an on-die functional unit (e.g., also referred to as a digital block or IP block) which can be fully integrated into digital domain areas. The frequency monitor 102 receives the clock signal 106 and outputs an indication 108 of whether the clock signal 106 is outside the expected frequency range. Alternatively, the frequency monitor 102 can output an indication that the clock signal 106 is within the expected frequency range.

As illustrated in FIG. 1, in at least one embodiment, the frequency monitor 102 includes a signal generator circuit 110, a voltage divider circuit 112, and digital logic circuitry 114. The voltage divider circuit 112 can include a configurable poly-resistor 116 and a switched-capacitor structure 118 coupled in series. The signal generator circuit 110 can be a non-overlapping converter, and an output of the non-overlapping converter is sent to the switched-capacitor structure 118. The switched-capacitor structure 118 has an effective resistance that is proportional to a frequency of the clock signal 106. An output signal 122 of the voltage divider circuit 112 is compared to one or more reference voltages to determine whether the output signal 122, which represents the frequency of the clock signal 106, is within the specified frequency range.

In at least one embodiment, the signal generator circuit 110 can receive the clock signal 106 and generate a set of phase signals 120. The voltage divider circuit 112 can receive the set of phase signals 120 from the signal generator circuit 110 and can convert, using the phase signals 120, a frequency of the clock signal 106 to a voltage representing the frequency. The voltage divider circuit 112 includes at least the resistor 116 and the switched-capacitor structure 118 to receive the set of phase signals 120 and generate the output signal 122 with the voltage representing the frequency. An average resistance of the switched-capacitor structure 118 is inversely proportional to the frequency of the clock signal 106. The voltage divider circuit 112 outputs the output signal 122. The digital logic circuitry 114 can receive the output signal 122 and determine, using the voltage, whether the frequency is outside of a specified frequency range and output an indication 108 responsive to the frequency being outside the specified frequency range.

In a further embodiment, the voltage divider circuit 112 includes a set of one or more programmable resistor(s) 124 coupled in parallel with the resistor 116. The programmable resistor(s) 124 can be programmable to adjust a total resistance of the resistor 116 and the programmable resistor(s) 124.

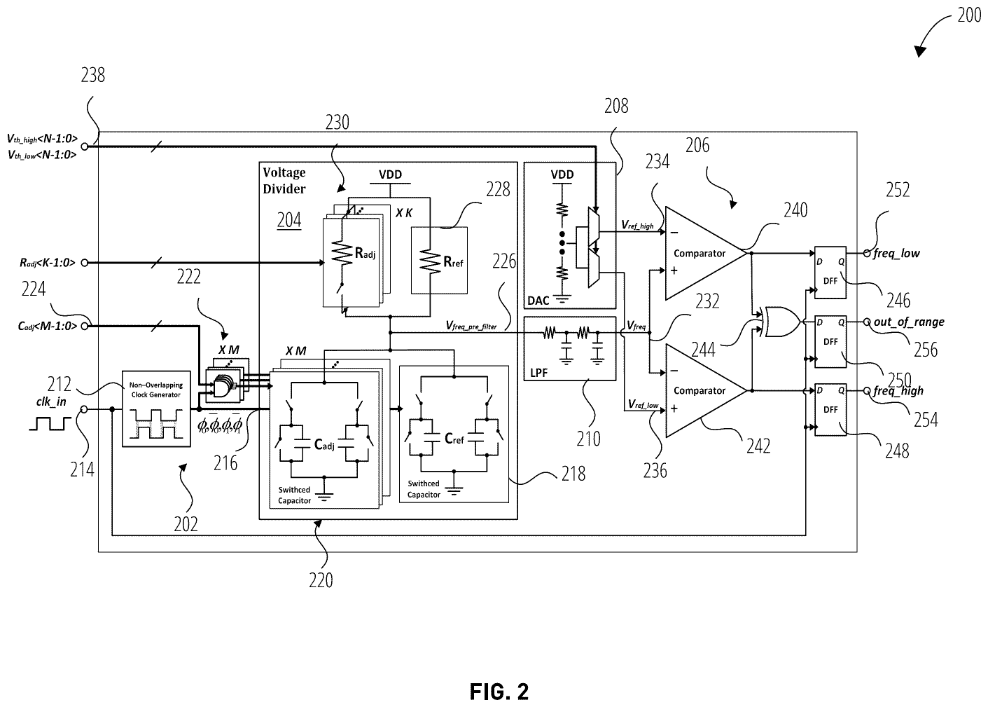

In a further embodiment, the voltage divider circuit 112 includes a set of one or more programmable switched-capacitor structure(s) 126 coupled in parallel with the switched-capacitor structure 118. The programmable switched-capacitor structure(s) 126 can be programmable to adjust a total effective resistance of the switched-capacitor structure 118 and the programmable switched-capacitor structure(s) 126, where the total effective resistance is inversely proportional to the frequency of the clock signal 106. The fully digital domain integrated frequency monitor 102 can be implemented using various architectures, such as the architecture illustrated and described below with respect to FIG. 2.

FIG. 2 is a circuit diagram of a fully digital domain integrated frequency monitor 200 according to at least one embodiment. The frequency monitor 200 can be similar to the frequency monitor 102 of FIG. 1. The frequency monitor 200 includes a signal generator circuit 202, a voltage divider circuit 204, and a digital logic circuitry 206. The frequency monitor 200 also includes a digital-to-analog converter (DAC) 208, and a low-pass filter (LPF) 210.

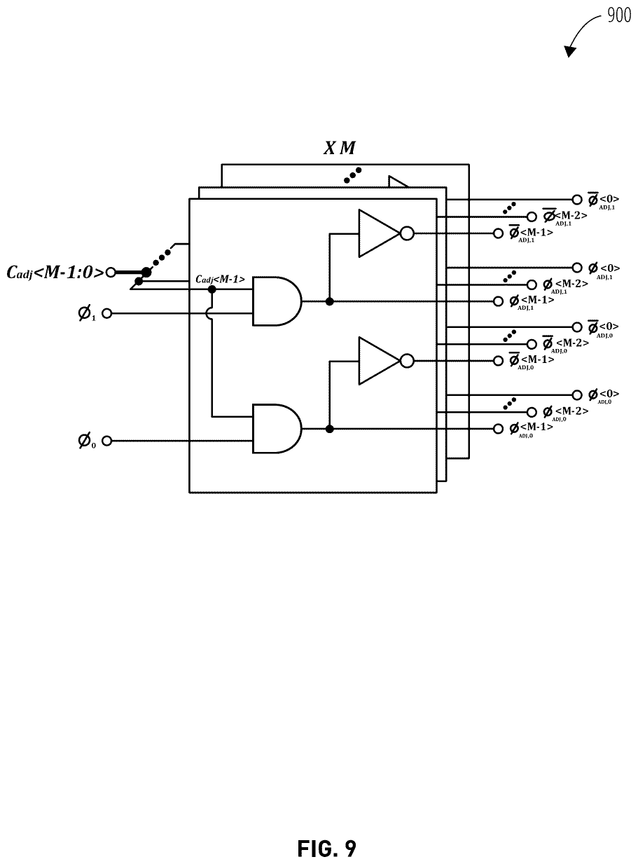

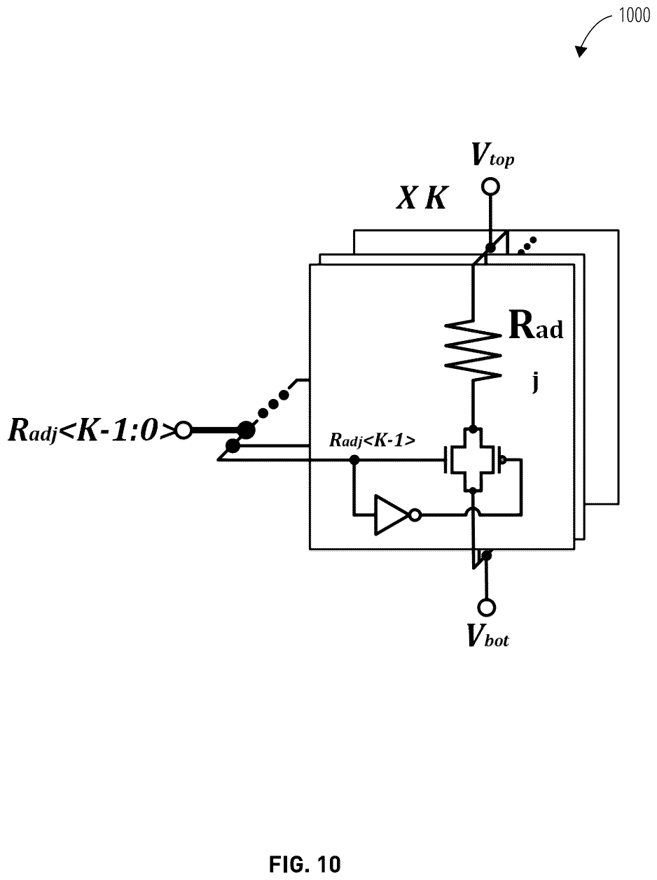

As illustrated in FIG. 2, the signal generator circuit 202 includes a non-overlapping clock generator 212 that receives a clock signal 214 and generates four phase signals 216 from the clock signal 214. The four phase signals 216, ϕₙ, ϕ̅ₙ̅, ϕ₁, ϕ̅₁̅, are differential non-overlapping clocks. The four phase signals 216 can be used to control the switched-capacitor structures of the voltage divider circuit 204. The voltage divider circuit 204 includes a set of configurable switched-capacitor bank, which serves as an “effective resistance,” in series with a set of configurable poly-resistors. The set of configurable poly resistors includes a first resistor 228 and a set of programmable resistors 230. The set of programmable resistors 230 includes K number of units used for calibration purposes, where each unit has an adjustable resistance (R_{adj}) in each of the units. Additional details of the set of programmable resistors 230 are described below with respect to FIG. 10. The switched-capacitor bank is divided into two banks. A first bank contains a first switched-capacitor structure 218, referred to as the C_{ref} capacitor, and a second bank of switched-capacitor structures 220 is used for calibration purposes. The second bank of switched-capacitor structures 220 contains M number of units of switched-capacitor structures with an adjustable capacitance (C_{adj}) in each of the units. The switched-capacitors differential non-overlapping clocks Ø_{adj,0} [symbol] M−1:0 [symbol] , Ø̅_̅{̅a̅d̅j̅,̅0̅}̅ [symbol] M−1:0 [symbol] , Ø_{adj,1} [symbol] M−1:0 [symbol] and Ø̅_̅{̅a̅d̅j̅,̅1̅}̅ [symbol] M−1:0 [symbol] are connected to each one of the units correspondingly, and come from clock gates 222, which are connected to Ø₀ and Ø₁ and enabled by a digital input configuration 224, C_{adj}<M−1:0>. Additional details of the clock gates 222 are described below with respect to FIG. 9. The switched-capacitor structure's “effective resistance” is proportional to the clock signal's frequency. Therefore, an average voltage level of an output voltage 226 (V_{freq_pre_filter}) of the voltage divider circuit 204 can be calculated, as expressed in the following equation (1):

$${\overline{V}}_{freq\_pre \_filtered} = VDD \cdot \frac{\frac{1}{{f}_{in} \cdot ( {C}_{ref} + m \cdot {C}_{adj} )}}{\frac{1}{{f}_{in} \cdot ( {C}_{ref} + m \cdot {C}_{adj} )} + {R}_{ref} \vert \vert \frac{{R}_{adj}}{k}} = \frac{VDD}{{f}_{in} \cdot ( {R}_{ref} \vert \vert \frac{{R}_{adj}}{k} ) ( {C}_{ref} + m \cdot {C}_{adj} ) + 1} \qquad ( 1 )$$

where m and k are the numbers of turned-on (activated) C_{adj} capacitors and R_{adj} resistors, respectively.

The output voltage 226 (V_{freq_pre_filter}) of the set of programmable resistors 230 can be filtered before the digital logic circuitry 206. In at least one embodiment, the output voltage 226 (V_{freq_pre_filter}) is sent to an LPF 210 to attenuate switching interferences. The LPF 210 outputs an output voltage 232 (V_{freq}) that has the same average voltage as the LPF input (V_{freq_pre_filter}) and is a function of the frequency of the 214, as set forth in the following equation (2).

$${\overline{V}}_{freq} = {\overline{V}}_{freq\_pre \_filtered} = VDD \cdot \frac{1}{{f}_{in} \cdot {R}_{tot} {C}_{tot} + 1} , \\ where {R}_{tot} = {R}_{ref} \vert \vert \frac{{R}_{adj}}{k} , \\ and where {C}_{tot} = {C}_{ref} + m \cdot {C}_{adj} \qquad ( 2 )$$

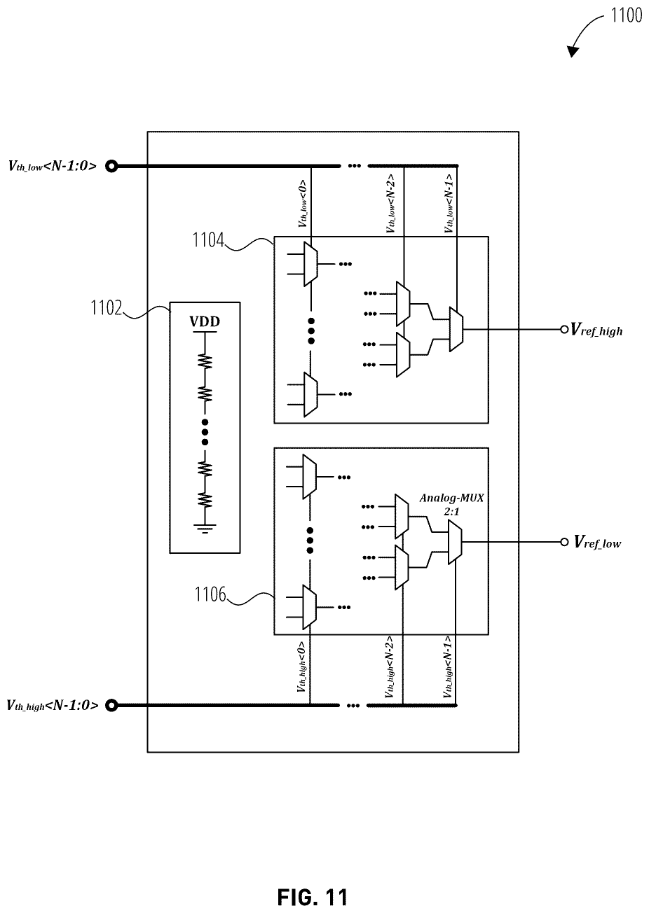

As illustrated in FIG. 2, the DAC 208 includes a resistor ladder of N poly-resistors connected to two configurable analog multiplexers, forming an N-bit DAC with two configurable and separated outputs, a first reference voltage 234 (V_{ref_high}) and a second reference voltage 236 (V_{ref_low}). Additional details of an N-bit Resistor-Ladder DAC are described below with respect to FIG. 11. The two output voltages of the DAC 208 (V_{ref_high} & V_{ref_low}) are controlled by digital input configuration 238, Vth_high<N−1:0> and V_{th_low}<N−1:0> binary digital inputs. The DAC's outputs can be expressed in equations (3) and (4) according to the resistive voltage divider (in the case of a uniform resistor-ladder with 2^{N} equal resistors):

$${V}_{ref \_ high} = VDD \cdot \frac{{\sum }_{j = 1}^{{n}_{low}} {R}_{j}}{{\sum }_{j = 1}^{N} {R}_{j}} = VDD \cdot \frac{{n}_{low , dec}}{{2}^{N}} \qquad ( 3 )$$

$${V}_{ref\_ low} = VDD \cdot \frac{{\sum }_{j = 1}^{{n}_{high}} {R}_{j}}{{\sum }_{j = 1}^{N} {R}_{j}} = VDD \cdot \frac{{n}_{high , dec}}{{2}^{N}} , \qquad ( 4 )$$

where N is the number of bits in the DAC 208 and n_{high,dec}, n_{low,dec} are the decimal representations of the Vth_high<N−1:0> and V_{th_low}<N−1:0> binary digital inputs correspondingly.

The digital logic circuitry 206 includes a first comparator 240, a second comparator 242, a logic gate 244, a first flip-flop 246, a second flip-flop 248, and a third flip-flop 250. The output voltage 232 is fed to the two comparators to be compared to the two reference voltages generated by the DAC 208. The comparators' outputs are sampled by digital flip-flops (DFFs), which can be clocked by the clock signal 214. In other embodiments, the DFFs are clocked by a sampling clock generated from another clock source, such as an internal ring oscillator. In at least one embodiment, the DAC 208 includes multiple resistors in a resistor ladder, a first analog multiplexer, and a second analog multiplexer. The first analog multiplexer is coupled to the resistor ladder. The first analog multiplexer can output the first reference voltage 234 based on a first digital value (digital input configuration 238). The first reference voltage 234 corresponds to a first frequency of the specified frequency range. The second analog multiplexer is coupled to the resistor ladder. The second analog multiplexer can output the second reference voltage 236 based on a second digital value (digital input configuration 238. The second reference voltage 236 corresponds to a second frequency of the specified frequency range.

When the output voltage 232, v̅_{freq} voltage, is larger than the first reference voltage 234, v_{ref high}, the first comparator's output will indicate that the frequency of the clock signal 214 is lower than the “low-frequency range threshold,” as set forth in the following equation (5):

$${\overline{V}}_{freq} > {V}_{ref\_ high} \qquad ( 5 )$$

$$⇓ \\ \cdot \frac{1}{{f}_{in} \cdot {R}_{tot} {C}_{tot} + 1} > \cdot \frac{{n}_{low , dec}}{{2}^{N}} \\ ⇓ \\ \frac{{2}^{N}}{{{n}_{low , dec}}^{}} > {f}_{in} \cdot {R}_{tot} {C}_{tot} + 1 \\ ⇓ \\ {f}_{in} < \frac{\frac{{2}^{N}}{{{n}_{low , dec}}^{}} - 1}{{R}_{tot} {C}_{tot}} = {f}_{th\_low}$$

Similarly, when the output voltage 232, v̅_{freq} voltage, is smaller than the second reference voltage 236, v_{ref low}, the second comparator's output can indicate that the frequency of the clock signal 214 is higher than the “high-frequency range threshold,” as set forth in the following equation (6):

$${f}_{in} > \frac{\frac{{2}^{N}}{{{n}_{high , dec}}^{}} - 1}{{R}_{tot} {C}_{tot}} = {f}_{th \_ high} \qquad ( 6 )$$

According to the equations above, the DAC's output can be selected such that different frequency thresholds can be compared to the output voltage 232 (representing the input clock's frequency). For equations (5) and (6), an adequate frequency range is needed, as expressed in equation (7):

$${n}_{low , dec} > {n}_{high , dec} \qquad ( 7 )$$

In at least one embodiment, the first comparator 240 can receive the output voltage 232 and the first reference voltage 234 corresponding to a first frequency of the specified frequency range. In this embodiment, the first reference voltage 234 (Vref_high) corresponds to a lower threshold of the specified frequency range. That is, when the frequency of the clock signal 214 increases, the output voltage 232 decreases and can cross the first reference voltage 234. The first comparator 240 can output a first output signal responsive to the output voltage 232 exceeding the first reference voltage 234. The first output signal can be a low-frequency indication 252. In at least one embodiment, the first flip-flop 246 is coupled to the first comparator 240 and can sample and hold a state of the first output signal. The second comparator 242 can receive the output voltage 232 and the second reference voltage 236 corresponding to a second frequency of the specified frequency range. In this embodiment, the second reference voltage 236 (Vref_low) corresponds to a higher threshold of the specified frequency range. That is, when the frequency of the clock signal 214 decreases, the output voltage 232 increases and can cross the second reference voltage 236. The second comparator 242 can output a second output signal responsive to the output voltage 232 exceeding the second reference voltage 236. The second output signal can be a high-frequency indication 254. In at least one embodiment, the second flip-flop can be coupled to the second comparator 242 and can sample and hold a state of the second output signal.

In at least one embodiment, the first flip-flop 246 and the second flip-flop 248 are clocked by the clock signal 214. In at least one embodiment, the frequency monitor 200 includes an oscillator (not illustrated in FIG. 2) that generates a second clock signal. The first flip-flop 246 and the second flip-flop 248 can be clocked by the second clock signal. In other embodiments, other internal clock sources can be used to clock the first flip-flop 246 and the second flip-flop 248. In at least one embodiment, a multiplexer or other type of selection circuit can be used to select between the clock signal 214 and the second clock signal to clock the digital logic circuitry 206.

In another embodiment, the digital logic circuitry 206 includes the first and second flip-flops described above and the logic gate 244 coupled to the first comparator 240 and the second comparator 242. The logic gate 244 can be an exclusive-OR gate (XOR) gate. The logic gate can output an indication responsive to the output voltage 232 exceeding the first reference voltage 234 or the second reference voltage 236. The indication can be an out-of-range indication 256. In this embodiment, the third flip-flop 250 can be coupled to the logic gate 244 to sample and hold a state of the logic gate. The 250 can output the out-of-range indication 256. It should be noted that the digital logic circuitry 206 can include other configurations of gates and DFFs to output one or more indications concerning the frequency of the clock signal 214.

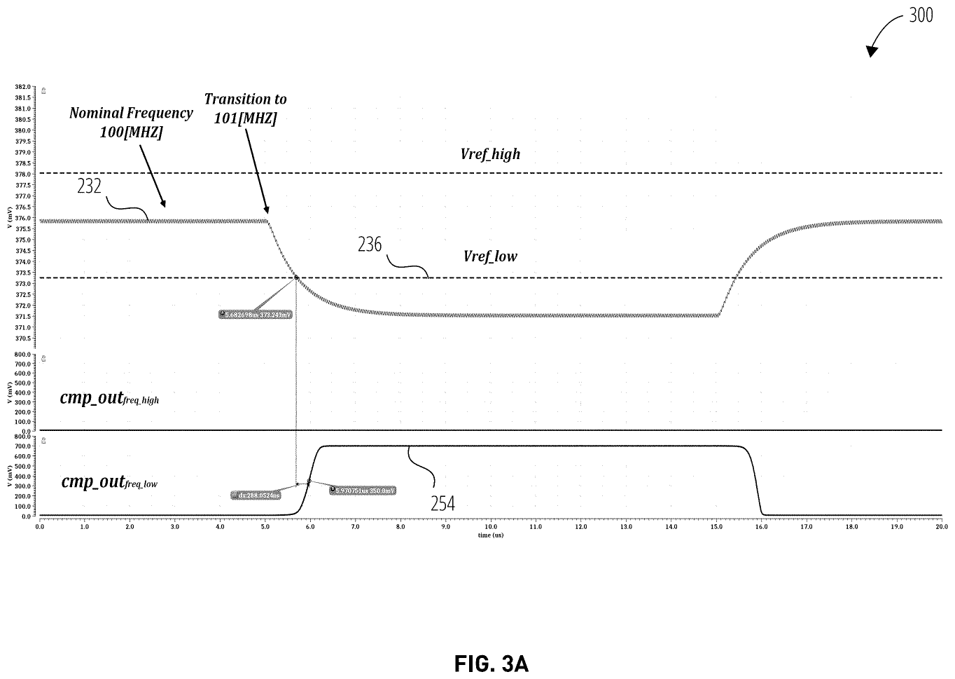

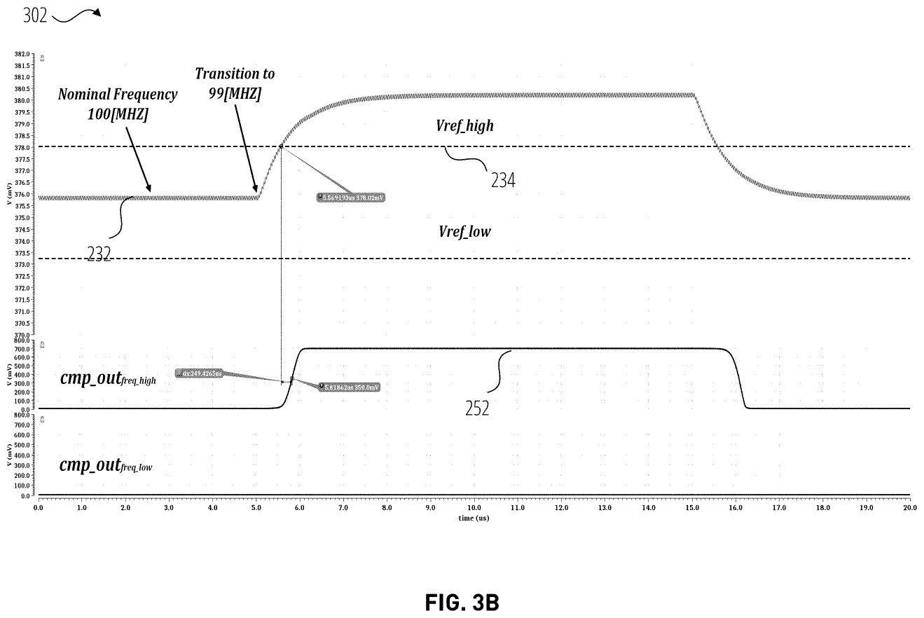

The following description with respect to FIG. 3A-3B sets forth two scenarios where the input clock frequency is raised to a higher frequency and returns to normal and where the input clock frequency is lowered to a lower frequency and returns to normal.

FIG. 3A is a graph 300 showing an input clock frequency being raised to a higher frequency according to at least one embodiment. The input clock frequency is the frequency of the clock signal 214. In this example, the input clock frequency is around 100 MHz and transitions to a higher frequency, 101 MHz. In the first example, the input clock frequency, as measured by the output voltage 232, decreases below the second reference voltage 236 (Vref_low), activating the high-frequency indication 254.

It can be seen in FIG. 3A that after the change in input clock frequency, the output voltage 232 (Vfreq) crosses the reference threshold voltages. The comparator output can change its polarity (e.g., the second comparator 242 in the first example and the first comparator 240 in the second example), and the DFFs' outputs also change. For example, when the input clock frequency rises above the threshold, the voltage in the Vfreq node becomes lower than the reference voltage in the Vref_low node. This causes the second comparator 242 to change from “0” to “1” since the comparator's negative input becomes smaller than the positive input. This indicates that the input clock frequency is higher and out of range.

FIG. 3B is a graph 302 showing an input clock frequency being reduced to a lowered frequency according to at least one embodiment. The input clock frequency is the frequency of the clock signal 214. In this example, the input clock frequency is around 100 MHz and transitions to a lower frequency, 99 MHz. In the second example, the input clock frequency, as measured by the output voltage 232, increases above the first reference voltage 234 (Vref_high), activating the low-frequency indication 252.

For example, when the input clock frequency decreases below the threshold, the voltage in the Vfreq node becomes higher than the reference voltage in the Vref_high node. This causes the first comparator 240 to change from “0” to “1” since the comparator's positive input becomes larger than the negative input. This indicates that the input clock frequency is lower and out of range.

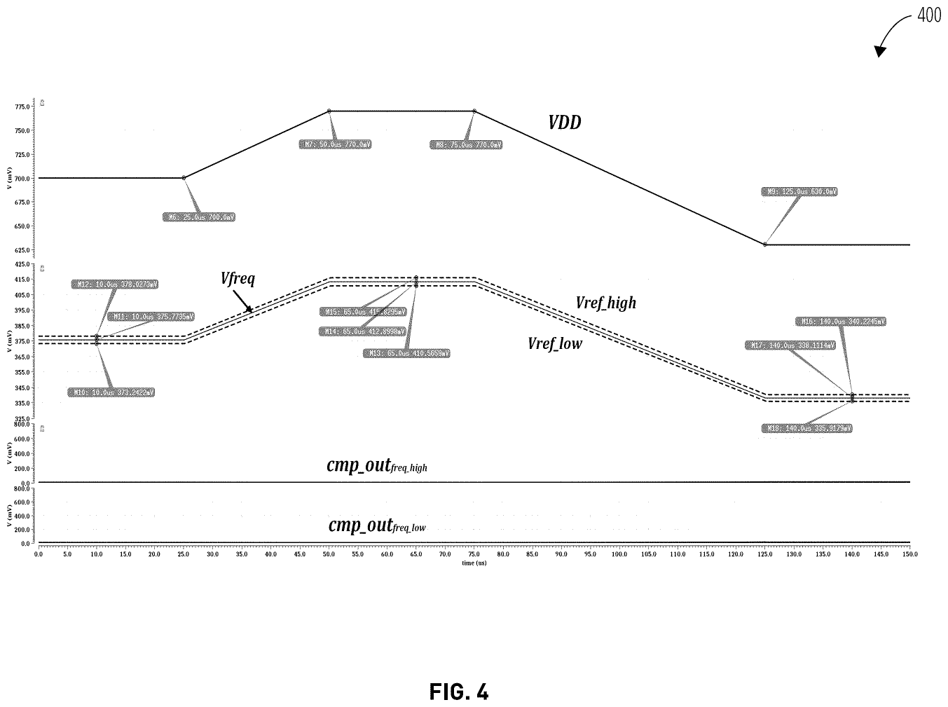

It should be noted that the frequency monitor 200 can have lower sensitivity to supply voltage variations and supply noise. Since the voltage divider circuit 204 and DAC 208 (two voltage dividers) use the same power supply (VDD) and their outputs (which are compared to each other) are proportional to the power supply, there is no direct impact by the supply voltage (VDD) as can be seen in the derivation of equation (5). Using the LPF 210 coupled to the output of the voltage divider circuit 204, the supply noise can be attenuated substantially. The nature of the DAC 208 can also have a low-pass transfer function. The supply voltage transitions as a function of time are illustrated in FIG. 4.

FIG. 4 is a graph 400 showing the supply voltage transitions as a function of time according to at least one embodiment. It can be seen that the output voltage 232 (V_{freq}), the first reference voltage 234 (V_{ref_high}), and the second reference voltage 236 (V_{freq_low}) are scaled similarly when the supply voltage (VDD) is changing. Therefore, the difference between the comparators' inputs stays the same.

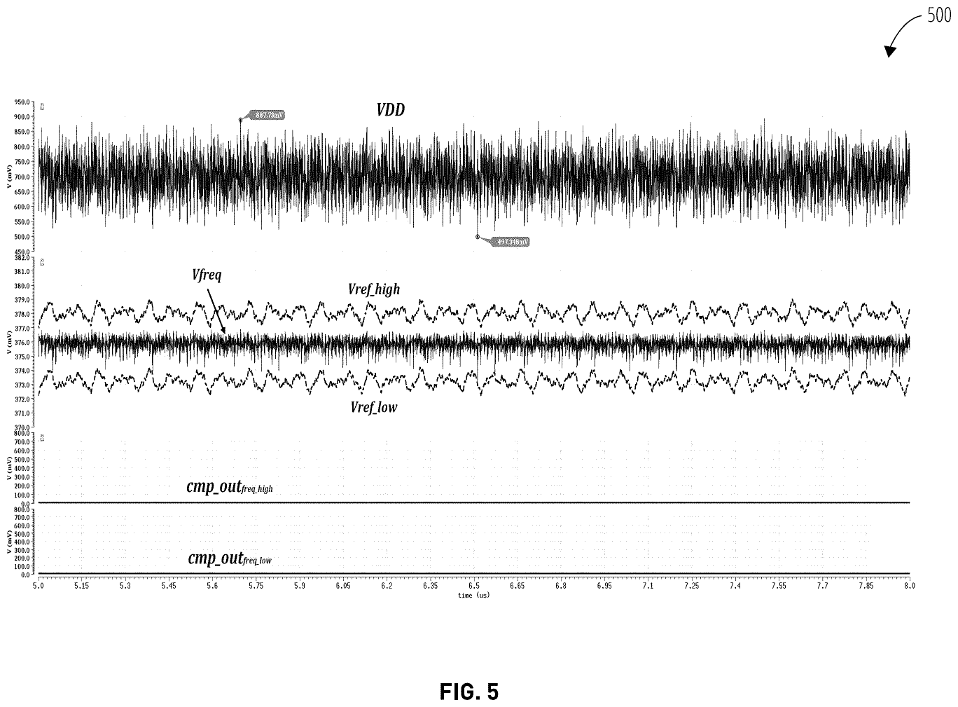

FIG. 5 is a graph 500 showing supply voltage noise attenuation according to at least one embodiment. As illustrated in graph 500, the noise over the supply voltage is attenuated dramatically, and the voltages of the output voltage 232 (V_{freq}), first reference voltage 234 (V_{ref_high}), and second reference voltage 236 (V_{freq} low) experience very low noise levels (sub millivolt). Therefore, the difference between the comparators' inputs stays approximately the same.

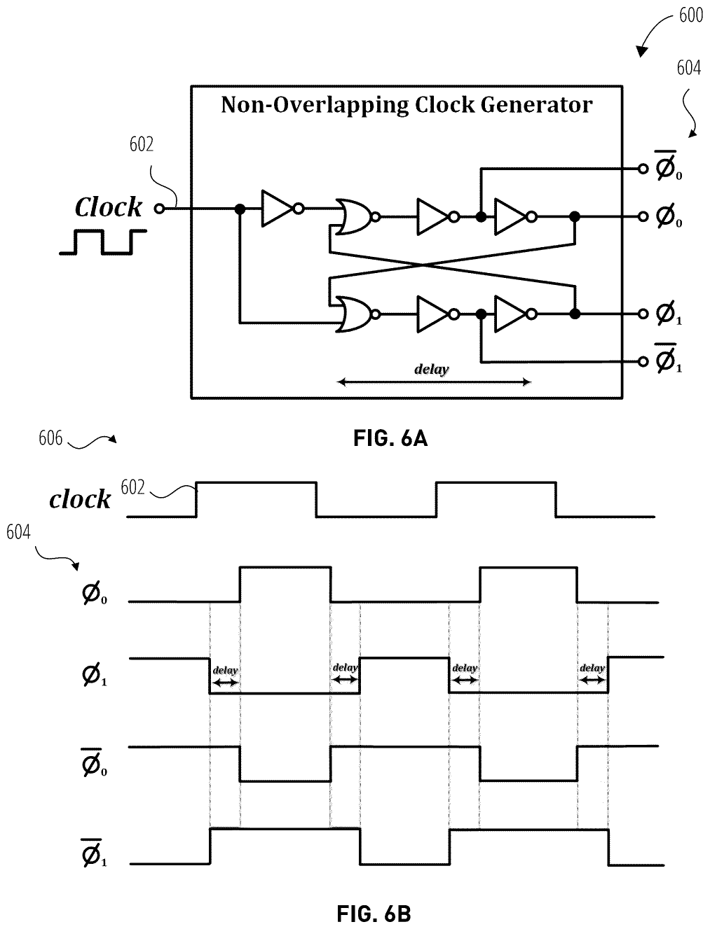

FIG. 6A is a circuit diagram of a non-overlapping clock generator 600 according to at least one embodiment. The non-overlapping clock generator 600 has an input clock 602, which can be the clock signal 214. The non-overlapping clock generator 600 generates two differential pairs of non-overlapped phase output clocks 604, ϕₙ, ϕ̅ₙ̅ and, ϕ₁, ϕ̅₁̅ as illustrated in FIG. 6B. The voltage divider circuit 204 can have fully differential switched-capacitor structures, so the non-overlapping differential output of the non-overlapping clock generator 600 is optimal for the next stage. The non-overlapping clock can prevent charge-sharing glitches between the capacitors, and the differential signaling allows using both NMOS & PMOS complementary CMOS switches.

FIG. 6B is a graph 606 illustrating an input clock 602 and four phase signals generated by the non-overlapping clock generator 600 of FIG. 6A according to at least one embodiment. The four phase signals in graph 606 are the two differential pairs of non-overlapped phase output clocks 604 generated by the non-overlapping clock generator 600.

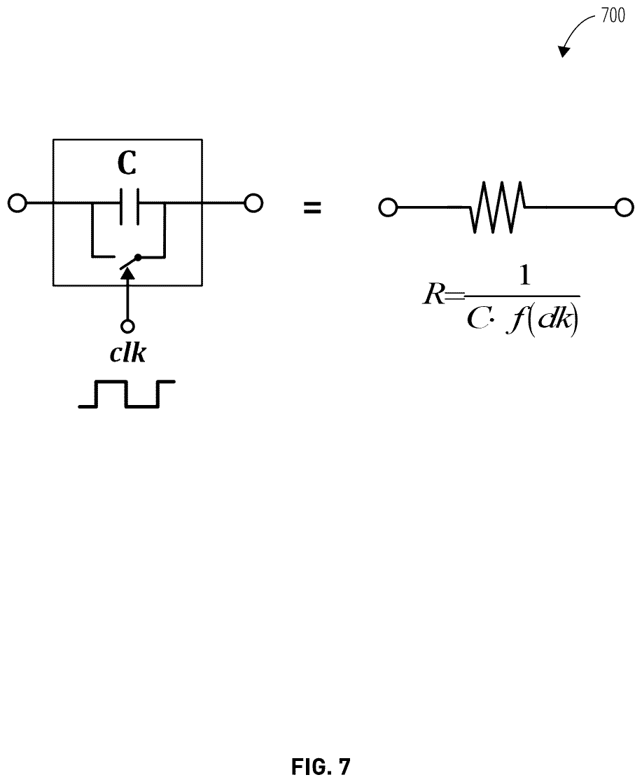

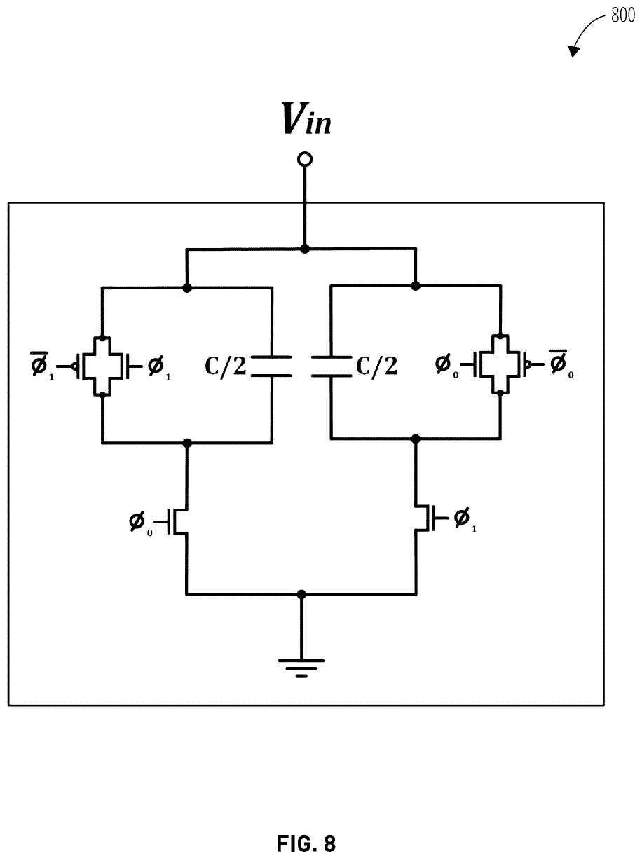

FIG. 7 illustrates an equivalent model of a switched-capacitor 700 as an effective resistor according to at least one implementation. A switch-capacitor is a commonly used technique that can be used for creating a component that has the average characteristics of a controlled resistor (its average resistance is inversely proportional to the frequency of its input clock). The charge flowing from two plates of a capacitive element at a certain frequency determines an equivalent resistance proportional to the capacitor and the operating frequency. In other words, if the two nodes of a capacitor are set with some voltage, the switched-capacitor 700 can be treated as a frequency-to-current converter. The switched-capacitor 700 can be implemented as a fully differential switched-capacitor structure, as illustrated and described below with respect to FIG. 8.

FIG. 8 is a schematic diagram of a fully differential switched-capacitor structure 800 according to at least one embodiment. The fully differential switched-capacitor structure 800 includes two capacitive elements coupled in parallel, each capacitive element being coupled in series with a respective switch. A transistor pair is coupled in parallel to each of the capacitive elements as well. In at least one embodiment, the fully differential switched-capacitor structure 800 represents the first switched-capacitor structure 218. In another embodiment, the fully differential switched-capacitor structure 800 represents one of the switched-capacitor structures 220. In order to configure the total capacitance value, Cₜₒₜ, there is a need to turn off/turn on the M number of switched-capacitor structures 220 (C_{adj}. The clock gates can be used for this purpose. Additional details of the clock gates are illustrated and described below with respect to FIG. 9.

FIG. 9 is a schematic diagram of clock gates 900 for the fully differential switched-capacitor structures according to at least one embodiment. In this embodiment, there are M blocks in parallel, each one receiving the two phase signals, the ϕ₀ & ϕ₁ non-overlapping clocks, at its inputs and having non-overlapping differential clocks as its inputs. The clock gates 900 turns off/on the M units of the switched-capacitor structures (C_{adj}), according to the C_{adj}<M−1:0> digital inputs. For example, the m^{th} block (m is between 0 to M−1) gets the C_{adj}<m> digital input and generates 4 non-overlapping differential output clocks: Ø_{adj,0} [symbol] m [symbol] , Ø̅_̅{̅a̅d̅j̅,̅0̅}̅ [symbol] m [symbol] , Ø_{adj,1} [symbol] m [symbol] and Ø̅_̅{̅a̅d̅j̅,̅1̅}̅ [symbol] m [symbol] . The total capacitance can be determined using the following equations (8) and (9):

$$When {C}_{adj} < m > = ‘ 0 ’ : \\ {⌀}_{adj , 0} 〈 m 〉 = ‘ 0 ’ , \overline{{⌀}_{adj , 0}} 〈 m 〉 = ‘ 1 ’ , {⌀}_{adj , 1} 〈 m 〉 = ‘ 0 ’ and \overline{{⌀}_{adj , 1}} 〈 m 〉 = ‘ 1 ’ \qquad ( 8 )$$

In this case, the corresponding m^{th} switched-capacitor structure is disconnected and is not counted as part of the Cₜₒₜ capacitance.

$$When {C}_{adj} < m > = ‘ 1 ’ : \\ {⌀}_{adj , 0} 〈 m 〉 = {⌀}_{0} , \overline{{⌀}_{adj , 0}} 〈 m 〉 = \overline{{⌀}_{0}} , {⌀}_{adj , 1} 〈 m 〉 = {⌀}_{1} and \overline{{⌀}_{adj , 1}} 〈 m 〉 = \overline{{⌀}_{1}} \qquad ( 9 )$$

In this case, the corresponding m^{th} switched-capacitor structure receives non-overlapping differential clocks at its inputs and is counted as part of the Cₜₒₜ capacitance.

The total Cₜₒₜ capacitance can be expressed in the following equation (10):

$${C}_{tot} = {C}_{ref} + m * {C}_{adj} , \qquad ( 10 )$$

where m is the number of turned-on switched-capacitor structures (C_{adj} units).

FIG. 10 is a schematic diagram of a programmable resistor according to at least one embodiment. A total resistance value, Rtot, can be adjusted for calibration purposes. The adjustment is made by connecting and disconnecting the K units of R_{adj} resistors in parallel to R_{ref}. A basic complementary switch can is used for this purpose. FIG. 10 shows the basic Radi unit. The digital R_{adj}<K−1:0> digital inputs control the number of resistors in parallel. The total Rₜₒₜ resistance is as follows in equation (11):

$${R}_{tot} = {R}_{reg} \vert \vert \frac{{R}_{adj}}{k} , \qquad ( 11 )$$

where k is the number of turned-on R_{adj} unit resistors and is between 0 to K. For k=0, Rtot=Rref.

FIG. 11 is a schematic diagram of an N-bit Resistor-Ladder DAC 1100 according to at least one embodiment. The N-bit Resistor-Ladder DAC 1100 can be the DAC 208 of FIG. 2. The N-bit Resistor-Ladder DAC 1100 can include a resistor ladder 1102, followed by two analog multiplexing circuits 1104, 1106. There are several possible architectures for the resistor ladder 1102 and the analog multiplexing circuits 1104, 1106. In at least one embodiment, the number of resistors in the resistor ladder 1102 can be equal to two to the power of N (2^{N}) equal resistors to form uniform steps across a full range from ground to the supply voltage. In at least one embodiment, the number of resistors in the resistor ladder 1102 can be equal to 2^{N} equal resistors in the middle with additional resistors on the top and bottom to form uniform steps across a narrower range of voltage references to reduce the step size and improve the resolution of the N-bit Resistor-Ladder DAC 1100. In at least one embodiment, the number of resistors in the resistor ladder 1102 can be equal to 2^{N} unequal resistors to form nonuniform steps across the range.

Since capacitors and poly-resistors suffer from variations in their capacitance and resistance values due to global and local mismatches in silicon production, calibration can be employed for increased accuracy. In at least one embodiment, basic calibration can be performed during the production phase of the integrated circuit by forcing a known input frequency and adjusting C_{adj}<M−1:0> & R_{adj}<K−1:0> digital inputs. Alternatively, the frequency thresholds can also be adjusted by forcing a known input frequency and adjusting V_{th_low}<N−1:0> & V_{th_high}<N−1:0> digital inputs. In other embodiments, the digital inputs can be calibrated using other techniques.

In at least one embodiment, calibration of the on-die switch-capacitors structures and resistors of the voltage divider circuit can be done with a known reference clock during the production phase. The VDD power supply for a processing core can be used, and an output voltage of the voltage divider circuit, referred to as Vref, can be compared to a reference voltage corresponding to the known reference clock. For example, the reference threshold can be half of VDD, compared to conventional solutions that use the full VDD. The quantization error can be very small for the DAC's resolution. The accuracy of the voltage divider circuit can be approximately ±25-30% (compared to greater than ±30% for conventional solutions), whereas after calibration it can be approximately ±2% (compared to greater than ±5% for conventional solutions). Also, better accuracy can be achieved by temperature compensation as well. The voltage divider circuit can consume approximately 0.2 mW where VDD is 0.64V (as compared to 1.35 mW for conventional solutions). The voltage divider circuit can also use less silicon area (e.g., 4,225 μm² vs. 19,600 μm² for conventional solutions).

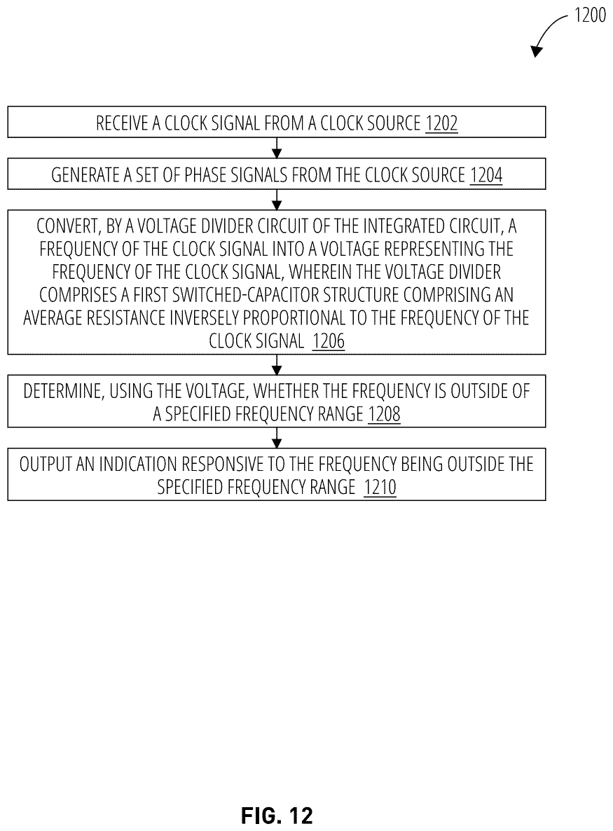

FIG. 12 is a flow diagram of a method 1200 for determining whether a frequency of a clock signal is outside a specified frequency range according to at least one embodiment. The method 1200 may be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 1200 is performed by the integrated circuit 100 of FIG. 1. In another embodiment, the method 1200 is performed by the frequency monitor 102 of FIG. 1. In another embodiment, the method 1200 is performed by frequency monitor 200 of FIG. 2.

Referring to FIG. 12, the method 1200 begins with the processing logic receiving a clock signal from a clock source (block 1202). At block 1204, the processing logic generates a set of phase signals from the clock source. At block 1206, the processing logic converts, by a voltage divider circuit of the integrated circuit, a frequency of the clock signal into a voltage representing the frequency of the clock signal. The voltage divider includes a first switched-capacitor structure comprising an average resistance inversely proportional to the frequency of the clock signal. At block 1208, the processing logic determines, using the voltage, whether the frequency is outside of a specified frequency range. At block 1210, the processing logic outputs an indication responsive to the frequency being outside the specified frequency range.

In a further embodiment, the processing logic compares the voltage to a first reference voltage corresponding to a first frequency of the specified frequency range. The processing logic generates a first output signal responsive to the voltage exceeding the first reference voltage. The processing logic compares the voltage to a second reference voltage corresponding to a second frequency of the specified frequency range. The processing logic generates a second output signal responsive to the voltage exceeding the second reference voltage, wherein the indication comprises the first output signal or the second output signal.

In at least one embodiment, the processing logic samples and holds a state of the first output signal. The processing logic samples and holds a state of the second output signal. The processing logic compares the voltage to a first reference voltage corresponding to a first frequency of the specified frequency range. The processing logic outputs a first output signal responsive to the voltage exceeding the first reference voltage. The processing logic compares the voltage to a second reference voltage corresponding to a second frequency of the specified frequency range. The processing logic outputs a second output signal responsive to the voltage exceeding the second reference voltage. The processing logic determines whether the voltage exceeds the first reference voltage or the second reference voltage. To output the indication, the processing logic outputs a third output signal responsive to the voltage exceeding the first reference voltage or the second reference voltage.

In at least one embodiment, the processing logic samples and holds a state of the first output signal, a state of the second output signal, and a state of the third output signal. In at least one embodiment, the processing logic receives a first value to program a set of programmable resistors of the voltage divider circuit. The processing logic programs the set of programmable resistors to adjust a first effective resistance of the voltage divider circuit based on the first value. The processing logic receives a second value to program a set of switched-capacitor structures of the voltage divider circuit. The processing logic programs the set of switched-capacitor structures to adjust a second effective resistance of the voltage divider circuit based on the second value. The second effective resistance is inversely proportional to the frequency of the clock signal.

In at least one embodiment, the processing logic receives a first value to program a first frequency of the specified frequency range. The processing logic programs a first analog multiplexer to provide a first reference voltage corresponding to the first frequency based on the first value. The processing logic receives a second value to program a second frequency of the specified frequency range. The processing logic programs a second analog multiplexer to provide a second reference voltage corresponding to the first frequency based on the second value.

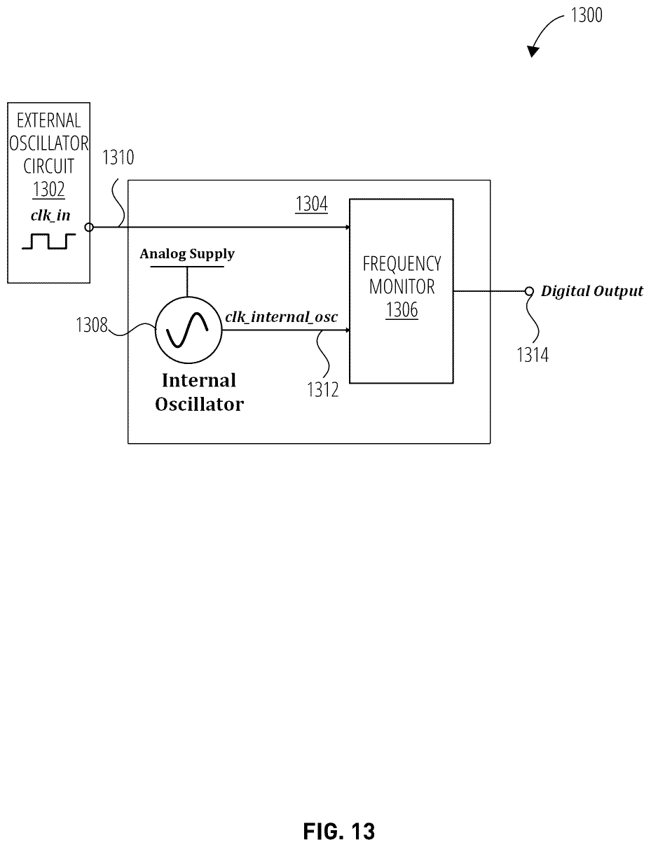

FIG. 13 is a block diagram of a computing system 1300 with a frequency monitor 1306 according to at least one embodiment. The computing system 1300 can be a CPU, a GPU, a DPU, a switch, a processor, a microprocessor, a microcontroller, or the like. The computing system 1300 includes an external oscillator circuit 1302 that generates a clock signal 1310 and an integrated circuit 1304. The integrated circuit 1304 includes the frequency monitor 1306 that can receive the clock signal 1310 from the external oscillator circuit 1302. The frequency monitor 1306 also receives an internal clock signal 1312 from an internal oscillator circuit 1308. The frequency monitor 1306 can be similar to the frequency monitor 102 of FIG. 1 or the frequency monitor 200 of FIG. 2. The frequency monitor 1306 can include a signal generator circuit that receives the clock signal 1310 and generates phase signals. The frequency monitor 1306 can include a voltage divider circuit that can receive the set of phase signals and convert a frequency of the clock signal 1310 to a voltage representing the frequency. The voltage divider circuit can include a first resistor and a first switched-capacitor structure to receive the set of phase signals. An average resistance of the first switched-capacitor structure is inversely proportional to the frequency of the clock signal. The frequency monitor 1306 can include digital logic circuitry that can determine, using the voltage, whether the frequency is outside of a specified frequency range. The digital logic circuitry can include sample-and-hold circuitry clocked using the clock signal 1312. The digital logic circuitry can output digital output 1314, including an indication responsive to the frequency being outside the specified frequency range.

The techniques disclosed herein may be incorporated in any processor that may be used for processing a neural network, such as, for example, a central processing unit (CPU), a GPU, an intelligence processing unit (IPU), a neural processing unit (NPU), a tensor processing unit (TPU), a neural network processor (NNP), a data processing unit (DPU), a vision processing unit (VPU), an application-specific integrated circuit (ASIC), a field-programmable gate array (FPGA), and the like. Such a processor may be incorporated in a personal computer (e.g., a laptop), at a data center, in an Internet of Things (IoT) device, a handheld device (e.g., smartphone), a vehicle, a robot, a voice-controlled device, or any other device that performs inference, training or any other processing of a neural network. Such a processor may be employed in a virtualized system such that an operating system executing in a virtual machine on the system can utilize the processor.

As an example, a processor incorporating the techniques disclosed herein can be employed to process one or more neural networks in a machine to identify, classify, manipulate, handle, operate, modify, or navigate around physical objects in the real world. For example, such a processor may be employed in an autonomous vehicle (e.g., an automobile, motorcycle, helicopter, drone, plane, boat, submarine, delivery robot, etc.) to move the vehicle through the real world. Additionally, such a processor may be employed in a robot at a factory to select components and assemble components into an assembly.

As an example, a processor incorporating the techniques disclosed herein can be employed to process one or more neural networks to identify one or more features in an image or alter, generate, or compress an image. For example, such a processor may be employed to enhance an image that is rendered using raster, ray-tracing (e.g., using NVIDIA RTX), and/or other rendering techniques. In another example, such a processor may be employed to reduce the amount of image data that is transmitted over a network (e.g., the Internet, a mobile telecommunications network, a WIFI network, as well as any other wired or wireless networking system) from a rendering device to a display device. Such transmissions may be utilized to stream image data from a server or a data center in the cloud to a user device (e.g., a personal computer, video game console, smartphone, other mobile devices, etc.) to enhance services that stream images such as NVIDIA Geforce Now (GFN), Google Stadia, and the like.

As an example, a processor incorporating the techniques disclosed herein can be employed to process one or more neural networks for any other types of applications that can take advantage of a neural network. For example, such applications may involve translating languages, identifying and negating sounds in audio, detecting anomalies or defects during the production of goods and services, surveillance of living beings and non-living things, medical diagnosis, making decisions, and the like.

Other variations are within the spirit of the present disclosure. Thus, while disclosed techniques are susceptible to various modifications and alternative constructions, certain illustrated embodiments are shown in drawings and described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if something is intervening. Recitation of ranges of values herein is merely intended to serve as a shorthand method of referring individually to each separate value falling within the range, unless otherwise indicated herein. Each separate value is incorporated into the specification as if it were individually recited herein. In at least one embodiment, the use of the term “set” (e.g., “a set of items”) or “subset” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., may be either A or B or C, or any nonempty subset of the set of A and B and C. For instance, in an illustrative example of a set having three members, conjunctive phrases “at least one of A, B, and C” and “at least one of A, B, and C” refers to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two but can be more when indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. In at least one embodiment, a set of non-transitory computer-readable storage media comprises multiple non-transitory computer-readable storage media and one or more individual non-transitory storage media of multiple non-transitory computer-readable storage media lacks all of the code, while multiple non-transitory computer-readable storage media collectively store all of the code. In at least one embodiment, executable instructions are executed such that different instructions are executed by different processors—for example, a non-transitory computer-readable storage medium stores instructions, and a main central processing unit (“CPU”) executes some of the instructions while a graphics processing unit (“GPU”) and/or a data processing unit (“DPU”)—potentially in conjunction with a GPU)—executes other instructions. In at least one embodiment, different components of a computer system have separate processors, and different processors execute different subsets of instructions.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of the disclosure, and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to actions and/or processes of a computer or computing system, or a similar electronic computing device, that manipulates and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transform that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, the terms “system” and “method” are used herein interchangeably insofar as a system may embody one or more methods, and methods may be considered a system.

In the present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface, or an interprocess communication mechanism.

Although descriptions herein set forth example embodiments of described techniques, other architectures may be used to implement described functionality, and are intended to be within the scope of this disclosure. Furthermore, although specific distributions of responsibilities may be defined above for purposes of description, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. An integrated circuit comprising:
a signal generator circuit to receive a clock signal and generate a plurality of phase signals;
a voltage divider circuit to receive the plurality of phase signals and convert a frequency of the clock signal to a voltage representing the frequency, wherein the voltage divider circuit comprises a first resistor and a first switched-capacitor structure to receive the plurality of phase signals, wherein an average resistance of the first switched-capacitor structure is inversely proportional to the frequency of the clock signal; and
digital logic circuitry coupled to the voltage divider circuit, the digital logic circuitry to determine, using the voltage, whether the frequency is outside of a specified frequency range, and output an indication responsive to the frequency being outside the specified frequency range.

2. The integrated circuit of claim 1, wherein the digital logic circuitry comprises:
a first comparator to receive the voltage and a first reference voltage corresponding to a first frequency of the specified frequency range, the first comparator to output a first output signal responsive to the voltage exceeding the first reference voltage; and
a second comparator to receive the voltage and a second reference voltage corresponding to a second frequency of the specified frequency range, the second comparator to output a second output signal responsive to the voltage exceeding the second reference voltage, wherein the indication comprises the first output signal or the second output signal.

3. The integrated circuit of claim 2, wherein the digital logic circuitry further comprises:
a first flip-flop coupled to the first comparator, the first flip-flop to sample and hold a state of the first output signal; and
a second flip-flop coupled to the second comparator, the second flip-flop to sample and hold a state of the second output signal.

4. The integrated circuit of claim 3, wherein the first flip-flop and the second flip-flop are clocked by the clock signal.

5. The integrated circuit of claim 3, further comprising an oscillator to generate a second clock signal, wherein the first flip-flop and the second flip-flop are clocked by the second clock signal.

6. The integrated circuit of claim 1, wherein the digital logic circuitry comprises:
a first comparator to receive the voltage and a first reference voltage corresponding to a first frequency of the specified frequency range, the first comparator to output a first output signal responsive to the voltage exceeding the first reference voltage;
a second comparator to receive the voltage and a second reference voltage corresponding to a second frequency of the specified frequency range, the second comparator to output a second output signal responsive to the voltage exceeding the second reference voltage; and
a logic gate coupled to the first comparator and the second comparator, the logic gate to output the indication responsive to the voltage exceeding the first reference voltage or the second reference voltage.

7. The integrated circuit of claim 6, wherein the digital logic circuitry further comprises:
a first flip-flop coupled to the first comparator, the first flip-flop to sample and hold a state of the first output signal;
a second flip-flop coupled to the second comparator, the second flip-flop to sample and hold a state of the second output signal; and
a third flip-flop coupled to the logic gate, the third flip-flop to sample and hold a state of the logic gate.

8. The integrated circuit of claim 7, further comprising an oscillator to generate a second clock signal, wherein the first flip-flop and the second flip-flop are clocked by the second clock signal.

9. The integrated circuit of claim 1, wherein the voltage divider circuit further comprises:
a set of programmable resistors coupled in parallel with the first resistor, wherein the set of programmable resistors is programmable to adjust a total resistance of the first resistor and the set of programmable resistors.

10. The integrated circuit of claim 1, wherein the voltage divider circuit further comprises:
a set of switched-capacitor structures coupled in parallel with the first switched-capacitor structure, wherein the set of switched-capacitor structures is programmable to adjust a total effective resistance of the first switched-capacitor structure and the set of switched-capacitor structures, wherein the total effective resistance is inversely proportional to the frequency of the clock signal.

11. The integrated circuit of claim 1, wherein the signal generator circuit is a non-overlapping clock generator circuit to generate four phase signals for the plurality of phase signals.

12. The integrated circuit of claim 1, further comprising a digital-to-analog converter (DAC) comprising;
a resistor ladder of multiple resistors;
a first analog multiplexer coupled to the resistor ladder, the first analog multiplexer to output a first reference voltage based on a first digital value, the first reference voltage corresponding to a first frequency of the specified frequency range; and
a second analog multiplexer coupled to the resistor ladder, the second analog multiplexer to output a second reference voltage based on a second digital value, the second reference voltage corresponding to a second frequency of the specified frequency range.

13. The integrated circuit of claim 1, further comprising a low-pass filter (LPF) coupled between the voltage divider circuit and the digital logic circuitry.

14. A method of operating an integrated circuit, the method comprising:
receiving a clock signal from a clock source;
generating a plurality of phase signals from the clock source;
converting, by a voltage divider circuit of the integrated circuit, a frequency of the clock signal into a voltage representing the frequency of the clock signal, wherein the voltage divider comprises a first switched-capacitor structure comprising an average resistance inversely proportional to the frequency of the clock signal;
determining, using the voltage, whether the frequency is outside of a specified frequency range; and
outputting an indication responsive to the frequency being outside the specified frequency range.

15. The method of claim 14, further comprising:
comparing the voltage to a first reference voltage corresponding to a first frequency of the specified frequency range;
generating a first output signal responsive to the voltage exceeding the first reference voltage;
comparing the voltage to a second reference voltage corresponding to a second frequency of the specified frequency range; and
generating a second output signal responsive to the voltage exceeding the second reference voltage, wherein the indication comprises the first output signal or the second output signal.

16. The method of claim 15, further comprising:
sampling and holding a state of the first output signal; and
sampling and holding a state of the second output signal.

17. The method of claim 15, further comprising:
comparing the voltage to a first reference voltage corresponding to a first frequency of the specified frequency range;
outputting a first output signal responsive to the voltage exceeding the first reference voltage;
comparing the voltage to a second reference voltage corresponding to a second frequency of the specified frequency range;
outputting a second output signal responsive to the voltage exceeding the second reference voltage; and
determining whether the voltage exceeds the first reference voltage or the second reference voltage, wherein the outputting the indication comprises outputting a third output signal responsive to the voltage exceeding the first reference voltage or the second reference voltage.

18. The method of claim 17, further comprising:
sampling and holding a state of the first output signal;
sampling and holding a state of the second output signal; and
sampling and holding a state of the third output signal.

19. The method of claim 14, further comprising:
receiving a first value to program a set of programmable resistors of the voltage divider circuit;
programming the set of programmable resistors to adjust a first effective resistance of the voltage divider circuit based on the first value;
receiving a second value to program a set of switched-capacitor structures of the voltage divider circuit; and
programming the set of switched-capacitor structures to adjust a second effective resistance of the voltage divider circuit based on the second value, wherein the second effective resistance is inversely proportional to the frequency of the clock signal.

20. The method of claim 14, further comprising:
receiving a first value to program a first frequency of the specified frequency range;
programming a first analog multiplexer to provide a first reference voltage corresponding to the first frequency based on the first value;
receiving a second value to program a second frequency of the specified frequency range; and
programming a second analog multiplexer to provide a second reference voltage corresponding to the second frequency based on the second value.

21. A computing system comprising:
an oscillator circuit to generate a clock signal; and
an integrated circuit coupled to the oscillator circuit, wherein the integrated circuit comprises:
a signal generator circuit to receive a clock signal and generate a plurality of phase signals;
a voltage divider circuit to receive the plurality of phase signals and convert a frequency of the clock signal to a voltage representing the frequency, wherein the voltage divider circuit comprises a first resistor and a first switched-capacitor structure to receive the plurality of phase signals, wherein an average resistance of the first switched-capacitor structure is inversely proportional to the frequency of the clock signal; and
digital logic circuitry coupled to the voltage divider circuit, the digital logic circuitry to determine, using the voltage, whether the frequency is outside of a specified frequency range, and output an indication responsive to the frequency being outside the specified frequency range.
